(19) United States
(12) Patent Application Publication
(10) Pub. No.: US 2012/0224308 A1
(43) Pub. Date: Sep. 6, 2012

(54) Electronic Apparatus and Locking Slot Set Thereof

(75) Inventors: Chih-Hao Lu, Taipei City (TW); Shu-Fang Chueh, Taipei City (TW)

(73) Assignee: PEGATRON CORPORATION, Taipei City (TW)

(21) Appl. No.: 13/409,644

(22) Filed: Mar. 1, 2012

(30) Foreign Application Priority Data
Mar. 1, 2011 (TW) 100106664

(51) Int. Cl. H05K 5/02; E05B 73/00

(52) U.S. Cl. 361/679.01; 70/58

(57) ABSTRACT

An electronic apparatus and a locking slot set thereof are disclosed. The locking slot set is used in the electronic apparatus for cooperating with a master lock, and the electronic apparatus includes a housing. The locking slot set includes a first locking slot and a second locking slot. The first locking slot is disposed on a first surface of the housing. The second locking slot is disposed adjacent to the first locking slot on the housing. The second locking slot and the first locking slot are connected to each other. At least one of the first locking slot and the second locking slot is used to be inserted by the master lock.

### BACKGROUND

1. Technology Field

The disclosure relates to a locking slot; in particular, to a locking slot set capable of providing functions of Kensington locking slot and strap slot at the same time and an electronic apparatus including the locking slot set.

2. Description of the Related Art

In general, Kensington lock is widely used for preventing a notebook from being stolen. Therefore, a Kensington locking slot is usually disposed on the housing of the notebook for being inserted by a locking member of the Kensington lock. Most housing of the notebook is formed by plastic material or thinner metal material, once the notebook is locked by the Kensington lock, if a thief wants to steal the notebook, the thief must force to pull out the locking member of the Kensington lock, and the housing of the notebook will be seriously damaged at the same time. Therefore, it is very hard for the thief to steal the locked notebook, and the theft rate of the notebook can be effectively reduced. In addition, a strap slot is usually disposed on the housing of the mobile communication apparatus, e.g., a smart phone, and used for the user to tie his/her favorite mobile phone strap.

With the development of the electrical technology, the size of the tablet computer between the size of conventional notebook and mobile communication apparatus has gradually popular with consumers. Because the tablet computer has features of notebook and mobile communication apparatus, the Kensington locking slot and the strap slot may be disposed on the tablet computer at the same time. In order to achieve good anti-theft effect, the Kensington locking slot disposed on the tablet computer will be performed a very strict pulling test in industry. And, considering the weight of the tablet computer is much heavier than that of the mobile phone, the test standard for the strap slot disposed on the tablet computer is much stricter than that for the strap slot disposed on the mobile phone. Therefore, the Kensington locking slot and the strap slot disposed on the tablet computer must be strengthened by their internal structures to meet the stricter test standard.

### SUMMARY

Therefore, the embodiment of the invention provides an electronic apparatus and a locking slot set thereof to solve the above-mentioned problems occurred in the prior arts.

The embodiment of the invention is to provide a locking slot set used in an electronic apparatus. The locking slot set is used to cooperate with a master lock, and the electronic apparatus includes a housing.

In an embodiment, the locking slot set includes a first locking slot and a second locking slot. The first locking slot is disposed on a first surface of the housing. The second locking slot is disposed adjacent to the first locking slot on the housing, and the second locking slot connects with the first locking slot. At least one of the first locking slot and the second locking slot is master lock.

In another embodiment, the master lock is a Kensington lock, and the at least one of the first locking slot and the second locking slot is a Kensington locking slot.

In another embodiment, the specification of the at least one of the first locking slot and the second locking slot includes a length ranging between 7 mm and 7.26 mm, a width ranging between 3 mm and 3.26 mm, and a maximum fillet radius of 1 mm.

In another embodiment, the second locking slot is also disposed on the first surface of the housing.

In another embodiment, the second locking slot is disposed on a second surface of the housing, the second surface is connected with the first surface, and an angle is existed between the first surface and the second surface.

In another embodiment, the locking slot set further includes a central cylinder disposed between the first locking slot and the second locking slot, wherein an object is capable of passing through the first locking slot and bypassing the central cylinder, and then passing through the second locking slot and being fixed on the central cylinder.

In another embodiment, the locking slot set further includes a locking slot support. The locking slot support is disposed on an inner wall of the housing, and the position of the locking slot support overlaps the position of the at least one of the first locking slot and the second locking slot.

In another embodiment, the locking slot support is formed by metal.

Another embodiment of the invention is to provide an electronic apparatus. The electronic apparatus is capable of being cooperated with a master lock.

In an embodiment, the electronic apparatus includes a housing and a locking slot set. The housing includes a first surface. The locking slot set includes a first locking slot and a second locking slot. The first locking slot is disposed on a first surface of the housing. The second locking slot is disposed adjacent to the first locking slot on the housing, and the second locking slot connects with the first locking slot. At least one of the first locking slot and the second locking slot is used to be inserted by the master lock.

In another embodiment, the master lock is a Kensington lock, and the at least one of the first locking slot and the second locking slot is a Kensington locking slot.

In another embodiment, the specification of the at least one of the first locking slot and the second locking slot includes a length ranging between 7 mm and 7.26 mm, a width ranging between 3 mm and 3.26 mm, and a maximum fillet radius of 1 mm.

In another embodiment, the second locking slot is also disposed on the first surface of the housing.

In another embodiment, the second locking slot is disposed on a second surface of the housing, the second surface is connected with the first surface, and an angle is existed between the first surface and the second surface.

In another embodiment, the locking slot set further includes a central cylinder disposed between the first locking slot and the second locking slot, wherein an object is capable of passing through the first locking slot and bypassing the central cylinder, and then passing through the second locking slot and being fixed on the central cylinder.

In another embodiment, the locking slot set further includes a locking slot support. The locking slot support is disposed on an inner wall of the housing, and the position of the locking slot support overlaps the position of the at least one of the first locking slot and the second locking slot.

In another embodiment, the locking slot support is formed by metal.

Compared to the prior arts, the electronic apparatus and its locking slot set of the embodiment of the invention can provide functions of Kensington locking slot and strap slot at the same time, and the sharing hole, fixing structure, and the internal strengthening structure are shared by the Kensington locking slot and the strap slot disposed in the minimum space in the housing of the tablet computer. Therefore, the embodiment of the invention can effectively reduce the volume and cost of the tablet computer to largely increase the competitiveness of the tablet computer on the market.

The advantage and spirit of the invention may be understood by the following detailed descriptions together with the appended drawings.

### BRIEF DESCRIPTION OF THE APPENDED DRAWINGS

FIG. 1 illustrates a schematic diagram of an electronic apparatus in a preferred embodiment of the invention.

FIG. 2 illustrates a schematic diagram of the first locking slot and the second locking slot disposed on the first surface of the housing at the same time.

FIG. 3A illustrates a schematic diagram of the Kensington lock.

FIG. 3B illustrates a schematic diagram of the locking slot support.

FIG. 4 illustrates a schematic diagram of the specification of the Kensington locking slot capable of containing the passing of the Kensington lock.

FIG. 5 illustrates a schematic diagram that the first locking slot is capable of meeting the specification of the Kensington locking slot, but the second locking slot fails.

FIG. 6 illustrates a schematic diagram of inserting the Kensington lock into the first locking slot.

FIG. 7 illustrates a schematic diagram of passing the strap through the first locking slot and the second locking slot of the locking slot set and hanging the strap in the central cylinder.

FIG. 8A illustrates a schematic diagram of the first locking slot and the second locking slot located on a side surface and a bottom surface of the housing respectively.

FIG. 8B illustrates a schematic diagram of inserting the Kensington lock into the first locking slot located on the side surface of the housing.

FIG. 8C illustrates a schematic diagram of inserting the Kensington lock into the second locking slot located on the bottom surface of the housing.

### DETAILED DESCRIPTION

A preferred embodiment of the invention is an electronic apparatus. In this preferred embodiment, the electronic apparatus is a tablet computer, but not limited to this. The electronic apparatus can be cooperated with a master lock, and it can provide functions of Kensington locking slot and strap slot at the same time.

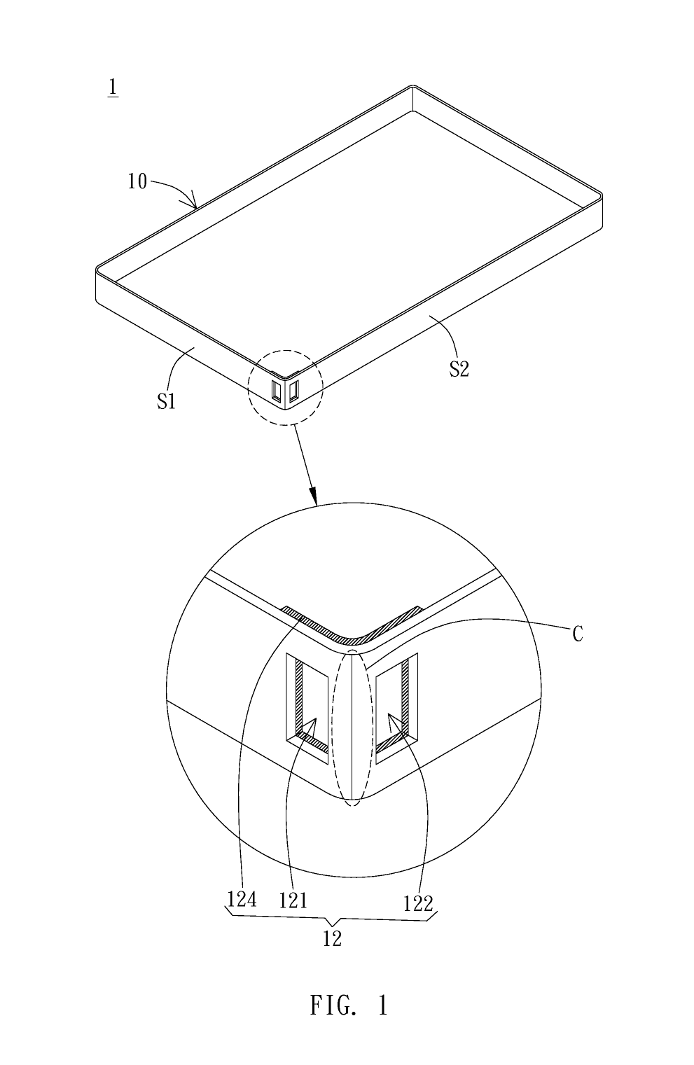

Please refer to FIG. 1. FIG. 1 illustrates a schematic diagram of the electronic apparatus in this embodiment. As shown in FIG. 1, the electronic apparatus 1 includes a housing 10 and a locking slot set 12. The housing 10 includes a first surface S1 and a second surface S2. The first surface S1 are connected with the second surface S2, and an angle is existed between the first surface S1 and the second surface S2. The locking slot set 12 includes a first locking slot 121, a second locking slot 122, a locking slot support 124, and a central cylinder C. The first locking slot 121 and the second locking slot 122 are disposed adjacent to each other on the housing 10. The central cylinder C is disposed between the first locking slot 121 and the second locking slot 122, and the first locking slot 121 and the second locking slot 122 can connect to each other through the inner space of the housing 10. The locking slot support 124 is disposed on an inner wall of the housing 10, and the position of the locking slot support 124 overlaps the position of the at least one of the first locking slot 121 and the second locking slot 122. The locking slot support 124 is used to support the first locking slot 121 and the second locking slot 122 and enhance the strength of their structures to meet the strict test standard. In fact, the locking slot support 124 can be formed by metal material, such as metal panels or Magnesium alloy castings, but not limited to this.

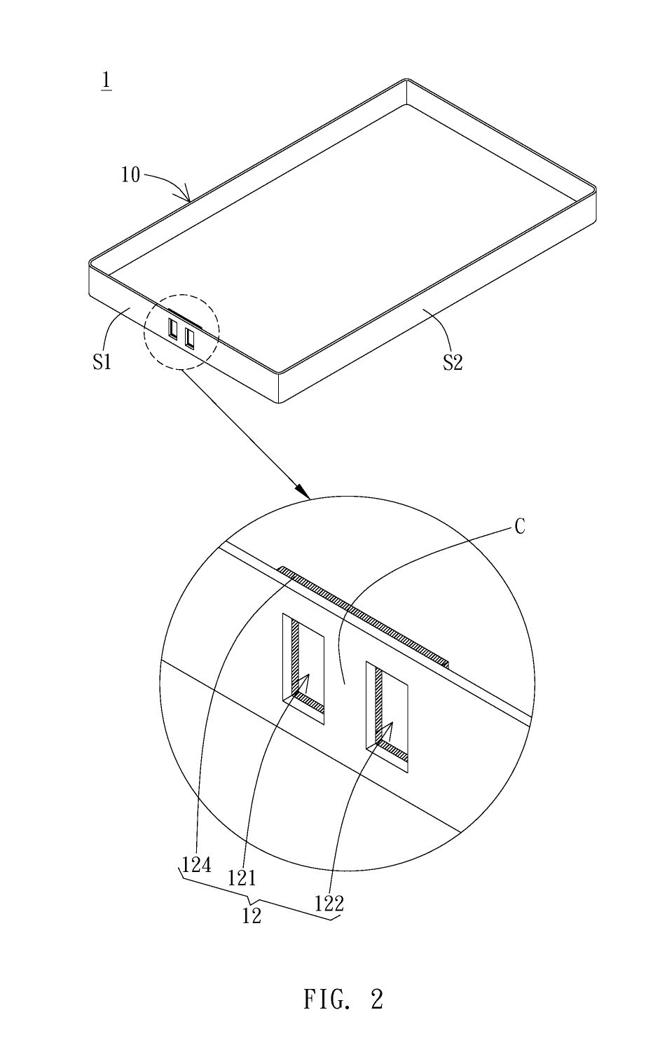

Please refer to FIG. 1 and FIG. 2, the first locking slot 121 and the second locking slot 122 of FIG. 1 are disposed on the first surface S1 and the second surface S2 of the housing 10 respectively, that is to say, the two locking slots on the housing 10 of the electronic apparatus 1 in FIG. 1 are disposed on the two surfaces of the housing 10 respectively instead of the same surface of the housing 10, and the two surfaces are connected to each other and an angle is existed between them. In fact, the first locking slot 121 and the second locking slot 122 on the housing 10 of the electronic apparatus 1 can be disposed on any two connecting surfaces of the housing 10 respectively based on practical needs and an angle is existed between them, and there is no specific limitation.

In FIG. 2, the first locking slot 121 and the second locking slot 122 are disposed on the first surface S1 of the housing 10 at the same time. In fact, the first locking slot 121 and the second locking slot 122 on the housing 10 of the electronic apparatus 1 can be disposed on the second surface S2 of the housing 10 at the same time, or disposed on other surfaces of the housing 10 at the same time without any specific limitations.

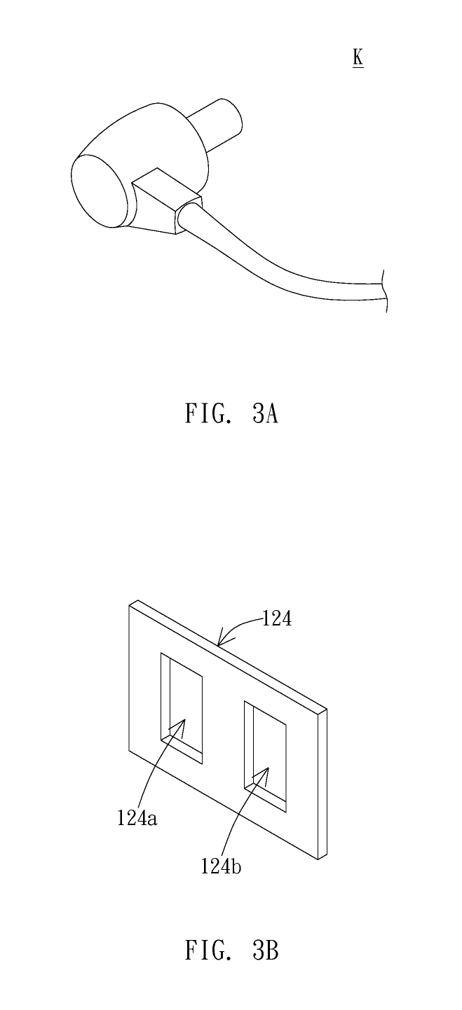

In this embodiment, since the electronic apparatus 1 has to be cooperated with the widely used master lock, Kensington lock K, as shown in FIG. 3, at least one of the first locking slot 121 and the second locking slot 122 of the locking slot set 12 should contain the passing of the Kensington lock K. That is to say, at least one of the first locking slot 121 and the second locking slot 122 of the locking slot set 12 must be larger than the Kensington lock K, so that the Kensington lock K can smoothly pass through the at least one locking slot. FIG. 3B illustrates a schematic diagram of the locking slot support 124. As shown in FIG. 3B, the locking slot support 124 has a first hole 124a and a second hole 124b corresponding to the first locking slot 121 and the second locking slot 122 of the locking slot set 12 respectively. In fact, the locking slot support 124 can be disposed on the inner part of any one surface or the connection of two surfaces of the housing 10 without any specific limitations.

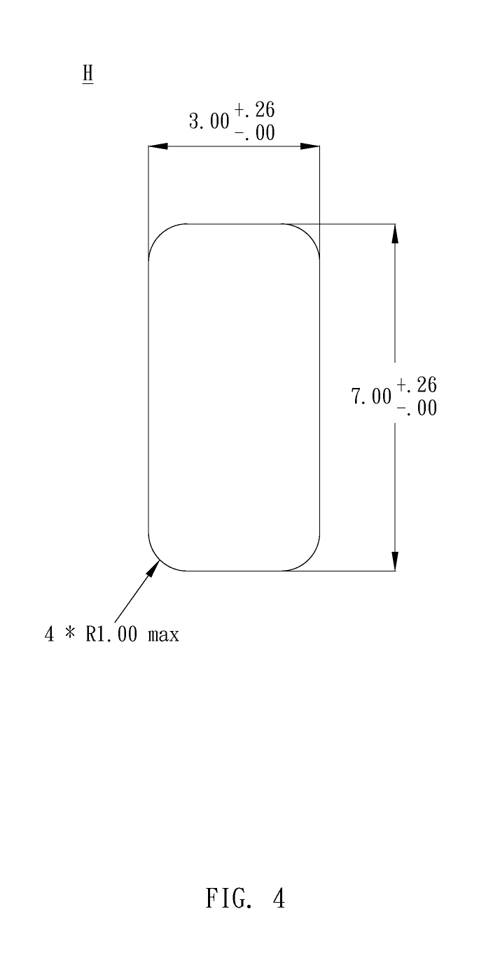

Please refer to FIG. 4. FIG. 4 illustrates a schematic diagram of the specification of the Kensington locking slot H capable of containing the passing of the Kensington lock K. As shown in FIG. 4, the length of the Kensington locking slot H ranges between 7 mm and 7.26 mm, the width of the Kensington locking slot H ranges between 3 mm and 3.26 mm, and the maximum fillet radius of the Kensington locking slot H is 1 mm. For example, the first locking slot 121 and the second locking slot 122 shown in FIG. 1 and FIG. 2 can meet the specification of the Kensington locking slot H, that is to say, the first locking slot 121 and the second locking slot 122 shown in FIG. 1 and FIG. 2 can both contain the passing of the Kensington lock K. Therefore, when the user wants to use the Kensington lock K to lock the electronic apparatus 1, no matter the user selects to insert the Kensington lock K into the first locking slot 121 or the second locking slot 122, the electronic apparatus 1 can be smoothly locked.

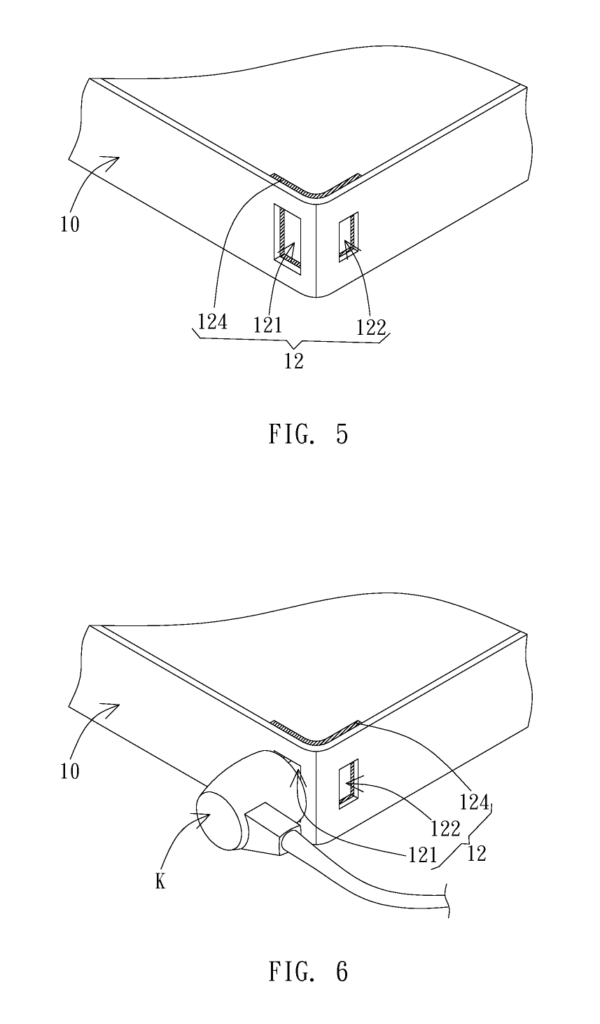

On the other hand, in another condition, only one of the first locking slot 121 and the second locking slot 122 of the locking slot set 12 can meet the specification of the Kensington locking slot H. As shown in FIG. 5, the first locking slot 121 can meet the specification of the Kensington locking slot H, but the second locking slot 122 is obviously smaller and fails to meet the specification of the Kensington locking slot H. Therefore, when the user wants to use the Kensington lock K to lock the electronic apparatus 1, the user can only insert the Kensington lock K into the first locking slot 121 as shown in FIG. 6, but the user fails to insert the Kensington lock K into the second locking slot 122. In fact, it can be the condition that the second locking slot 122 can meet the specification of the Kensington locking slot H, but the first locking slot 121 fails to meet the specification of the Kensington locking slot H. Therefore, there is no specific limitation.

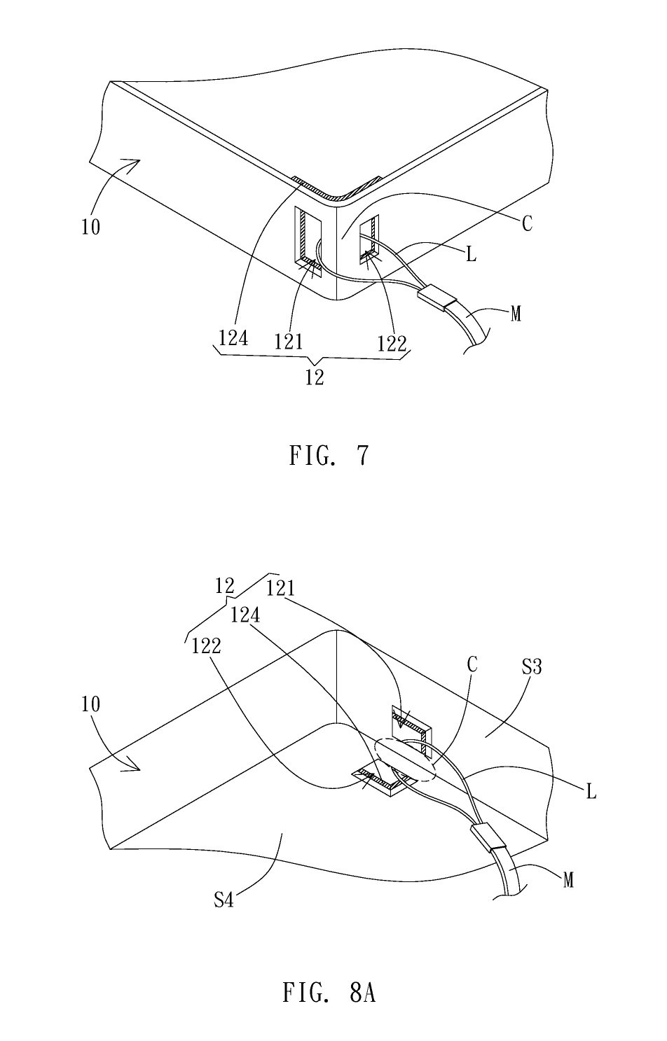

In the embodiment, the first locking slot 121 and the second locking slot 122 of the locking slot set 12 can also used as the strap slot. Please refer to FIG. 7. FIG. 7 illustrates a schematic diagram of passing the strap M through the first locking slot 121 and the second locking slot 122 of the locking slot set 12 and hanging the strap M in the central cylinder C. As shown in FIG. 7, no matter the first locking slot 121 and the second locking slot 122 of the locking slot set 12 are disposed on the same surface or adjacent surfaces of the housing 10, the central cylinder C is located between the first locking slot 121 and the second locking slot 122, and the first locking slot 121 and the second locking slot 122 can connected to each other through the inner space of the housing 10. Therefore, a line L of the strap M can pass through the first locking slot 121 and bypass the central cylinder C, and then the line L can pass through the second locking slot 122 and then fixed on the central cylinder C. In fact, the line L of the strap M can be fixed on the central cylinder C in a way of being tied on the central cylinder C, but not limited to this.

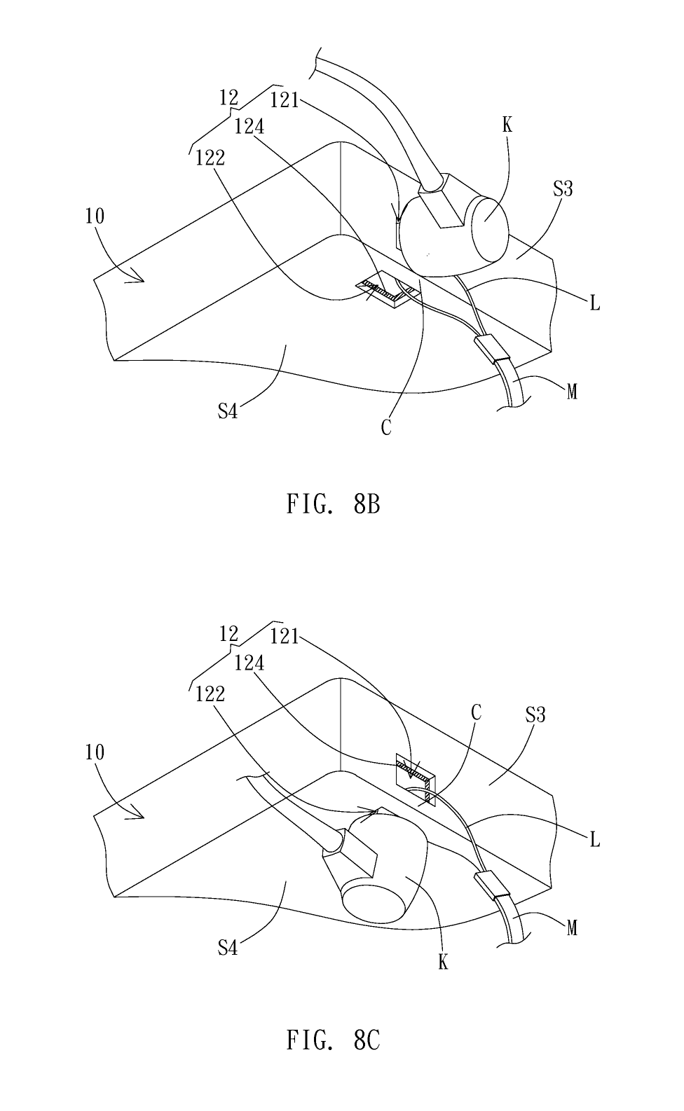

In the embodiment, the position distribution design of the first locking slot 121 and the second locking slot 122 of the locking slot set 12 can be different based on practical needs. Not only the horizontal direction distribution of the first locking slot 121 and the second locking slot 122 mentioned above, but also the vertical distribution of the first locking slot 121 and the second locking slot 122 can be used for the locking slot set 12. As shown in FIG. 8A, the first locking slot 121 and the second locking slot 122 are disposed on the side surface S3 and the bottom surface S4 of the housing 10 respectively, and the first locking slot 121 and the second locking slot 122 both meet the specification of the Kensington locking slot H. The user can tie the line L of the strap M on the central cylinder C to fix the strap M on the central cylinder C. Therefore, the user can select to insert the Kensington lock K into the first locking slot 121 of the side surface S3 of the housing 10 (as shown in FIG. 8B), or insert the Kensington lock K into the second locking slot 122 of the bottom surface S4 of the housing 10 (as shown in FIG. 8C).

Another preferred embodiment of the invention is a locking slot set. In this embodiment, the locking slot set is used in an electronic apparatus for cooperating with a master lock, and the locking slot set is capable of providing functions of the Kensington locking slot and strap slot at the same time. The electronic apparatus includes a housing. The locking slot set at least includes a first locking slot and a second locking slot. The first locking slot is disposed on a first surface of the housing. The second locking slot is disposed adjacent to the first locking slot on the housing, and the second locking slot connects with the first locking slot. At least one of the first locking slot and the second locking slot is used to be inserted by the master lock.

In the embodiment, the electronic apparatus may be a tablet computer and the master lock may be the Kensington lock, but not limited to this. As to the detailed structure and operation of the locking slot set in this embodiment, please refer to the above-mentioned description and figures, it will not be repeated here.

Compared to the known technology, the electronic apparatus and its locking slot set of the invention can provide functions of Kensington locking slot and strap slot at the same time, and the sharing hole, fixing structure, and the internal strengthening structure are shared by Kensington locking slot and strap slot disposed in the minimum space in the housing of the tablet computer. Therefore, the invention can effectively reduce the volume and cost of the tablet computer to largely increase the competitiveness of the tablet computer on the market.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A locking slot set, used in an electronic apparatus for cooperating with a master lock, and the electronic apparatus comprising a housing, the locking slot set at least comprising:
a first locking slot, disposed on a first surface of the housing; and
a second locking slot, disposed adjacent to the first locking slot on the housing, and the second locking slot connecting with the first locking slot;
wherein at least one of the first locking slot and the second locking slot is used to be inserted by the master lock.

2. The locking slot set of claim 1, wherein the master lock is a Kensington lock, and the at least one of the first locking slot and the second locking slot is a Kensington locking slot.

3. The locking slot set of claim 2, wherein the specification of the at least one of the first locking slot and the second locking slot comprises a length ranging between 7 mm and 7.26 mm, a width ranging between 3 mm and 3.26 mm, and a maximum fillet radius of 1 mm.

4. The locking slot set of claim 1, wherein the second locking slot is disposed on the first surface of the housing.

5. The locking slot set of claim 1, wherein the second locking slot is disposed on a second surface of the housing, the second surface is connected with the first surface, and an angle is existed between the first surface and the second surface.

6. The locking slot set of claim 1, comprising a central cylinder disposed between the first locking slot and the second locking slot, wherein an object is capable of passing through the first locking slot and bypassing the central cylinder, and then passing through the second locking slot and being fixed on the central cylinder.

7. The locking slot set of claim 1, further comprising:
a locking slot support, disposed on an inner wall of the housing, and the position of the locking slot support overlaps the position of the at least one of the first locking slot and the second locking slot.

8. The locking slot set of claim 7, wherein the locking slot support is formed by metal.

9. An electronic apparatus, capable of being cooperated with a master lock, the electronic apparatus at least comprising:
a housing, comprising a first surface; and
a locking slot set, comprising:
a first locking slot, disposed on a first surface of the housing; and
a second locking slot, disposed adjacent to the first locking slot on the housing, and the second locking slot connecting with the first locking slot;
wherein at least one of the first locking slot and the second locking slot is used to be inserted by the master lock.

10. The electronic apparatus of claim 9, wherein the master lock is a Kensington lock, and the at least one of the first locking slot and the second locking slot is a Kensington locking slot.

11. The electronic apparatus of claim 10, wherein the specification of the at least one of the first locking slot and the second locking slot comprises a length ranging between 7 mm and 7.26 mm, a width ranging between 3 mm and 3.26 mm, and a maximum fillet radius of 1 mm.

12. The electronic apparatus of claim 9, wherein the second locking slot is also disposed on the first surface of the housing.

13. The electronic apparatus of claim 9, wherein the second locking slot is disposed on a second surface of the housing, the second surface is connected with the first surface, and an angle is existed between the first surface and the second surface.

14. The electronic apparatus of claim 9, wherein the locking slot set further comprises a central cylinder disposed between the first locking slot and the second locking slot, and an object is capable of passing through the first locking slot and bypassing the central cylinder, and then passing through the second locking slot and being fixed on the central cylinder.

15. The electronic apparatus of claim 9, wherein the locking slot set further comprises:
a locking slot support disposed on an inner wall of the housing, and the position of the locking slot support overlaps the position of the at least one of the first locking slot and the second locking slot.

16. The electronic apparatus of claim 15, wherein the locking slot support is formed by metal.
